(19) United States
(12) Patent Application Publication
(10) Pub. No.: US 2025/0347813 A1
(43) Pub. Date: Nov. 13, 2025

(54) X-RAY DETECTION PANEL, X-RAY DETECTOR COMPRISING THE SAME, AND UNIT PIXEL FOR THE SAME

(71) Applicant: DUOPIX-RAY INC., Daejeon (KR)

(72) Inventor: Seung Ik JUN, Frisco, TX (US)

(21) Appl. No.: 18/861,966

(22) PCT Filed: Apr. 1, 2024
(86) PCT No.: PCT/KR2024/004133

§ 371 Date: Oct. 31, 2024

(30) Foreign Application Priority Data
Sep. 13, 2023 (KR) 10-2023-0121556

(51) Int. Cl. G01T 1/20; G01T 1/24; H10F 30/29

(52) U.S. Cl. CPC G01T 1/20184; G01T 1/247; H10F 30/29

(57) ABSTRACT

Disclosed are an X-ray detection panel, an X-ray detector including the same, and a unit pixel for the same. The X-ray detection panel includes a plurality of unit pixels each including a photodiode, a first readout thin-film transistor, and a second readout thin-film transistor, wherein the first and second readout thin-film transistors are electrically connected to the photodiode and are connected in series to each other.

### TECHNICAL FIELD

The present invention relates to an X-ray detection panel having improved X-ray detection sensitivity, an X-ray detector including the same, and a unit pixel for the same.

### BACKGROUND ART

X-ray detectors are used in a wide range of applications, including medical equipment used in hospitals and dental offices for diagnostic X-ray imaging; industrial equipment for inspection of internal defects of electric vehicle batteries, semiconductors, electronic components, buildings, aircrafts, and ships; equipment for security screening of cargo at airports and port facilities; and military equipment for detection of hazardous materials such as explosives.

Dynamic X-ray detectors are used in both medical and industrial applications. In industrial applications, dynamic X-ray detectors play a crucial role in non-destructive testing, which is essential to ensure the safety and reliability of products, such as electric vehicle batteries and semiconductors. In medical applications, dynamic X-ray detectors are used in C-arm CT, cone-beam CT, and breast CT for breast cancer screening.

Such a dynamic X-ray detector requires high frames per second, minimal image lag, and minimal ghost images to achieve high-speed image acquisition.

An X-ray detector includes an X-ray detection panel as an image sensor. The X-ray detection panel utilizes a photodiode to detect visible light emitted from a scintillator.

FIG. 1 is a schematic layout diagram of an X-ray detection panel of a typical dynamic X-ray detector.

Referring to FIG. 1, a typical X-ray detection panel includes a plurality of unit pixels (N, N+1, N+2, . . . ), wherein each unit pixel includes a readout thin-film transistor Readout TFT and a photodiode.

A readout terminal of the readout thin-film transistor, that is, a drain, is connected to a readout IC through a readout pad, and a gate of the readout thin-film transistor is connected to a readout gate IC through a readout gate pad. The photodiode is connected to a bias voltage terminal through a bias pad.

When irradiated with X-rays, a scintillator is excited by the X-rays and emits visible light, which, in turn, is delivered to the photodiode to generate electrical charges. The charges generated in the photodiode are transferred to the readout pad by the read out thin-film transistor to generate an image signal.

Typical dynamic X-ray detection panels can suffer from problems such as low sensitivity, image lag, and ghost images due to incomplete removal of parasitic capacitance components from the photodiode before and after image acquisition. Furthermore, in typical X-ray detection panels, the quantity of current transferred through the readout thin-film transistor is considerably low (about 1.0 μA), resulting in significantly low brightness (sensitivity) of a final digital image acquired through analog-to-digital conversion (ADC).

In particular, increase in frames per second during high-speed dynamic X-ray image acquisition results in a shorter X-ray exposure time per frame, causing reduction in sensitivity (brightness) of a resulting image.

Sensitivity enhancement can be achieved through amplification of the digital gain of hardware or through software-based image processing to enhance image brightness after image acquisition. However, amplifying the digital gain of hardware to enhance image sensitivity results in increased noise in an image. Additionally, employing software-based image processing to enhance image brightness introduces trade-offs such as decreased resolution and makes high-speed dynamic frame acquisition difficult due to necessity of additional image processing time.

### DISCLOSURE

### Technical Problem

It is one aspect of the present invention to provide an X-ray detection panel that can increase sensitivity without causing adverse effects such as increased image noise, decreased resolution, and additional image processing time, an X-ray detector including the same, and a unit pixel for the same.

It is another aspect of the present invention to provide an X-ray detection panel that can increase a readout output value of each unit pixel in the X-ray detection panel, an X-ray detector including the same, and a unit pixel for the same.

It is a further aspect of the present invention to provide an X-ray detection panel that can prevent image lag or generation of ghost images due to parasitic capacitance components accumulated at a photodiode, an X-ray detector including the same, and a unit pixel for the same.

### Technical Solution

In accordance with one aspect of the present invention, an X-ray detection panel is provided. The X-ray detection panel includes a plurality of unit pixels each including: a photodiode; a first readout thin-film transistor; and a second readout thin-film transistor, wherein the first readout thin-film transistor and the second readout thin-film transistor are electrically connected to the photodiode and are connected in series to each other.

A source of the first readout thin-film transistor and a source of the second readout thin-film transistor may be connected in common to the photodiode, a gate of the first readout thin-film transistor and a gate of the second readout thin-film transistor may be connected to each other, and a drain of the first readout thin-film transistor and a drain of the second readout thin-film transistor may be connected to each other.

The X-ray detection panel may further include: readout pads; readout gate pads; and a bias pad, wherein the readout pads may be connected to the drains of the first and second readout thin-film transistors, the readout gate pads may be connected to the gates of the first and second readout thin-film transistors, and the bias pad may be connected to the photodiode.

In one embodiment, the gates of the first and second readout thin-film transistors may be connected to the readout gate pad through a readout gate line, the drains of the first and second readout thin-film transistors may be connected to the readout pad through a readout drain line, and the photodiode may be connected to the source of the second readout thin-film transistor. Each unit pixel may further include a capacitor disposed between the first readout thin-film transistor and the readout gate line.

In addition, each unit pixel may further include a capacitor disposed between the second readout thin-film transistor and the readout gate line.

In one embodiment, the gates of the first and second readout thin-film transistors may be connected to the readout gate pad through a readout gate line, the photodiode may be connected to the sources of the first and second readout thin-film transistors, and each unit pixel may further include a capacitor disposed between the readout gate line and the first and second readout thin-film transistors and a capacitor disposed between the second readout thin-film transistor and the readout gate line.

Each unit pixel may further include a reset thin-film transistor, wherein a source of the reset thin-film transistors may be connected to the sources of the first and second readout thin-film transistors and the photodiode.

The X-ray detection panel may further include: reset gate pads; and a reset drain pad, wherein the reset gate pad may be connected to a gate of the reset thin-film transistor, and the reset drain pad may be connected to a drain of the reset thin-film transistor.

The sources of the first and second readout thin-film transistors may be connected in common to the photodiode, the gates of the first and second readout thin-film transistors may be connected to each other, and the drains of the first and second readout thin-film transistors may be connected to each other.

In one embodiment, the X-ray detection panel may further include: readout pads; readout gate pads; and a bias pad, wherein the readout pads may be connected to the drains of the first and second readout thin-film transistors, the readout gate pads may be connected to the gates of the first and second readout thin-film transistors, and the bias pad may be connected to the photodiode.

The gates of the first and second readout thin-film transistors may be connected to the readout gate pad through a readout gate line, the drains of the first and second readout thin-film transistors may be connected to the readout pad through a readout drain line, the photodiode may be connected to the sources of the first and second readout thin-film transistors, and each unit pixel may further include a capacitor disposed between the first readout thin-film transistor and the readout gate line.

Each unit pixel may further include a capacitor disposed between the second readout thin-film transistor and the readout gate line.

In one embodiment, the gates of the first and second readout thin-film transistors are connected to the readout gate pad through a readout gate line, the photodiode may be connected to the sources of the first and second readout thin-film transistors; and each unit pixel may further include a capacitor disposed between the first readout thin-film transistor and the readout gate line and a capacitor disposed between the second readout thin-film transistor and the readout gate line.

In one embodiment, the gate of the reset thin-film transistor may be connected to the reset gate pad through a reset gate line, the source of the reset thin-film transistor may be connected to the sources of the first and second readout thin-film transistors and the photodiode, and each unit pixel may further include a capacitor disposed between the reset thin-film transistor and the reset gate line.

In one embodiment, each unit pixel may further include a capacitor disposed between the reset thin-film transistor and the reset gate line and a capacitor disposed between the first readout thin-film transistor and the readout gate line.

In one embodiment, each unit pixel may further include a capacitor disposed between the reset thin-film transistor and the reset gate line and a capacitor disposed between the second readout thin-film transistor and the readout gate line.

In one embodiment, each unit pixel may further include a capacitor disposed between the reset thin-film transistor and the reset gate line, a capacitor disposed between the first readout thin-film transistor and the readout gate line, and a capacitor disposed between the second readout thin-film transistor and the readout gate line.

In accordance with another aspect of the present invention, an X-ray detector is provided. The X-ray detector includes an X-ray detection panel, wherein the X-ray detection panel includes a plurality of unit pixels each comprising: a photodiode; a first readout thin-film transistor; and a second readout thin-film transistor, and the first readout thin-film transistor and the second readout thin-film transistor are electrically connected to the photodiode and are connected in series to each other.

In one embodiment, each unit pixel may further include a reset thin-film transistor.

In accordance with a further aspect of the present invention, a unit pixel for an X-ray detection panel is provided. The unit pixel includes: a photodiode; a first readout thin-film transistor; and a second readout thin-film transistor, wherein the first thin-film transistor and the second readout thin-film transistor are electrically connected to the photodiode and are connected in series to each other.

In one embodiment, the unit pixel may further include: at least one capacitor connected to the first readout thin-film transistor or the second readout thin-film transistor.

In one embodiment, the unit pixel may further include: a reset thin-film transistor.

The unit pixel may further include: at least one capacitor connected to one of the first readout thin-film transistor, the second readout thin-film transistor, and the reset thin-film transistor.

### Advantageous Effects

According to embodiments of the present invention, image sensitivity (brightness) of an X-ray detection panel can be enhanced by increasing the magnitude of readout output current. Furthermore, through introduction of a reset thin-film transistor, it is possible to solve problems such as image lag or ghost images caused by parasitic capacitance components. In addition, through incorporation of a capacitor, it is possible to eliminate noise components in a readout gate line or in an output line.

### DESCRIPTION OF DRAWINGS

FIG. 1 is a schematic layout diagram of an X-ray detection panel of a typical dynamic X-ray detector.

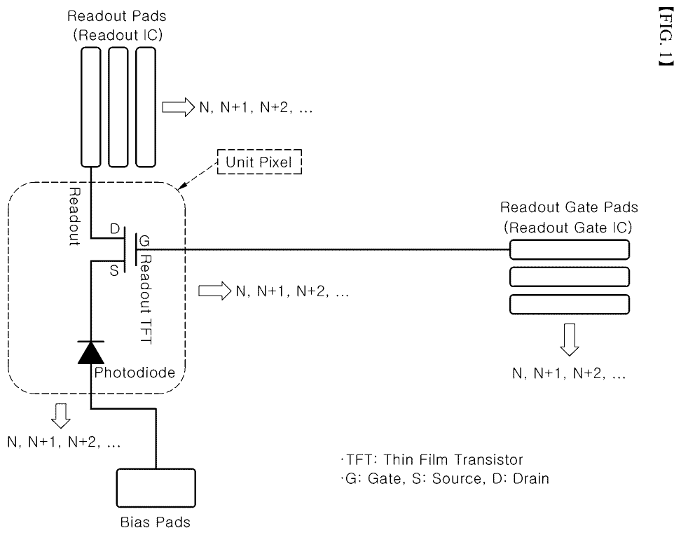

FIG. 2 is a schematic layout diagram of an X-ray detection panel according to one embodiment of the present invention.

FIG. 3 is a schematic layout diagram of an X-ray detection panel according to another embodiment of the present invention.

FIG. 4 is a schematic layout diagram of an X-ray detection panel according to a further embodiment of the present invention.

FIG. 5 is a schematic layout diagram of an X-ray detection panel according to yet another embodiment of the present invention.

FIG. 6 is a schematic layout diagram of an X-ray detection panel according to yet another embodiment of the present invention.

FIG. 7 is a schematic layout diagram of an X-ray detection panel according to yet another embodiment of the present invention.

FIG. 8 is a schematic layout diagram of an X-ray detection panel according to yet another embodiment of the present invention.

FIG. 9 is a schematic layout diagram of an X-ray detection panel according to yet another embodiment of the present invention.

FIG. 10 is a schematic layout diagram of an X-ray detection panel according to yet another embodiment of the present invention.

FIG. 11 is a schematic circuit diagram of an X-ray detection panel according to yet another embodiment of the present invention.

FIG. 12 is a schematic layout diagram of an X-ray detection panel according to yet another embodiment of the present invention.

FIG. 13 is a schematic layout diagram of an X-ray detection panel according to yet another embodiment of the present invention.

### BEST MODEL

Hereinafter, embodiments of the present invention will be described with reference to the accompanying drawings. It should be understood that the following embodiments are provided for complete disclosure and thorough understanding of the present invention by those skilled in the art. Therefore, the present invention is not limited to the following embodiments and may be embodied in different ways. In the drawings, the width, length, and thickness of components may be exaggerated for descriptive convenience and clarity. When an element is referred to as being “on”, “connected to”, or “coupled to” another element, it may be directly on, connected to, or coupled to the other element, or intervening elements may be present. It should be noted that like components will be denoted by like reference numerals throughout the specification and the accompanying drawings.

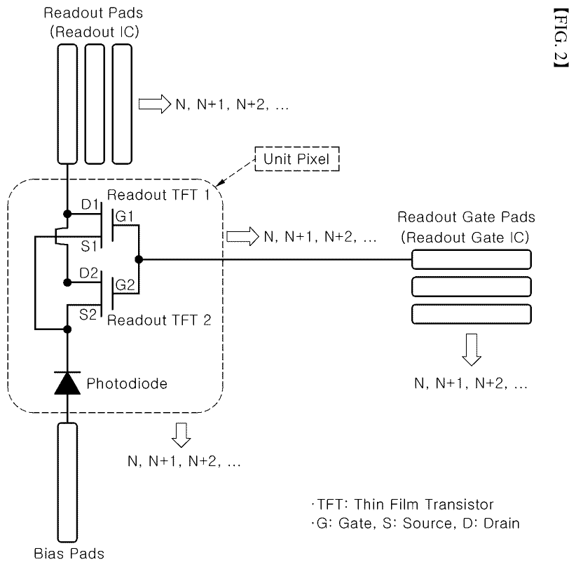

FIG. 2 is a schematic layout diagram of an X-ray detection panel of an X-ray detector according to one embodiment of the present invention. The X-ray detection panel described herein is suitable for an indirect X-ray detection method, in which visible light converted from X-rays by a scintillator is detected. However, the present invention is not limited thereto and the X-ray detection panel may be used in direct X-ray detection applications.

Referring to FIG. 2, the X-ray detection panel includes a plurality of unit pixels (N, N+1, N+2, . . . ), wherein each unit pixel includes a first readout thin-film transistor Readout TFT 1, a second readout thin-film transistor Readout TFT 2, and a photodiode. In addition, the X-ray detection panel includes readout pads, readout gate pads, and a bias pad which are connected to the plurality of unit pixels (N, N+1, N+2, . . . ).

The plurality of unit pixels may be arranged, for example, in a matrix, without being limited thereto. For example, the plurality of unit pixels may be arranged in a matrix of 5,000 rows and 5,000 columns.

The first and second readout thin-film transistors Readout TFT 1, Readout TFT 2 may be a switching device including at least one of amorphous silicon, polycrystalline silicon, In—Ga—Zn—O, or In—Zn—O as a semiconductor layer. The photodiode is a photoelectric conversion device and may include at least one of amorphous silicon, polycrystalline silicon, single-crystalline silicon, In—Ga—Zn—O, In—Zn—O, or In—Sn—O.

First, a connection structure of a unit pixel will be described in detail, focusing on the photodiode and the first and second readout thin-film transistors Readout TFT 1, Readout TFT 2.

A readout terminal of the first readout thin-film transistor Readout TFT 1, that is, a drain D1, is connected to a readout IC through the readout pad, and a gate G1 of the first readout thin-film transistor Readout TFT 1 is connected to a readout gate IC through the readout gate pad.

A readout terminal of the second readout thin-film transistor Readout TFT 2, that is, a drain D2, is connected to a readout IC through the readout pad, and a gate G2 of the second readout thin-film transistor Readout TFT 2 is connected to a readout gate IC through the readout gate pad. The drain D1 may be electrically connected to the drain D2, and the gate G1 may be electrically connected to the gate G2. The drain D1 and the drain D2 may be connected in common to the readout pad, and the gate G1 and the gate G2 may be connected in common to the readout gate pad.

The first and second readout thin-film transistors Readout TFT 1, Readout TFT 2 may be turned on and off by gate voltage V_{Gate} applied through the readout gate pad.

The photodiode is connected to a bias voltage terminal V_{Bias} through the bias pad. An anode of the photodiode may be connected to the bias pad, and a cathode of the photodiode may be connected to both a source S1 of the first readout thin-film transistor Readout TFT 1 and a source S2 of the second readout thin-film transistor Readout TFT 2.

The bias pad may be connected to all of the plurality of unit pixels (N, N+1, N+2, . . . ). That is, all the photodiodes in the detection panel may be connected in common to a single bias pad. Although one bias pad is shown in this embodiment, the present invention is not limited thereto and the detection panel may include a plurality of bias pads.

Charges generated by photoelectric conversion in the photodiode in response to incident X-rays accumulate at the sources S1, S2 of the readout thin-film transistors Readout TFT 1, Readout TFT 2. When readout gate voltage V_{Gate} is applied, the charges accumulated at the sources S1, S2 of the readout thin-film transistors Readout TFT 1, Readout TFT 2 are output to the readout pad through the drains D1, D2.

Unit pixels in the same row may be connected in common to a single readout gate pad, whereas unit pixels in different rows may be connected to different readout gate pads. Specifically, the gates G1, G2 of the readout thin-film transistors Readout TFT 1, Readout TFT 2 of each unit pixel in the same row are connected in common to a single readout gate pad. Conversely, the gates G1, G2 of the readout thin-film transistors Readout TFT 1, Readout TFT 2 of each unit pixel in one row and the gates G1, G2 of the readout thin-film transistors Readout TFT 1, Readout TFT 1 of each unit pixel in another row are connected to different readout gate pads.

Alternatively, unit pixels in the same column may be connected in common to a single readout pad, whereas unit pixels in different columns may be connected to different readout pads. Specifically, the gates G1, G2 of the readout thin-film transistors Readout TFT 1, Readout TFT 2 of each unit pixel in the same column are connected in common to a single readout gate pad. Conversely, the gates G1, G2 of the readout thin-film transistors Readout TFT 1, Readout TFT 2 of each unit pixel in one column and the gates G1, G2 of the readout thin-film transistors Readout TFT 1, Readout TFT 1 of each unit pixel in another column are connected to different readout gate pads. Accordingly, unit pixels in the same row are connected to different readout pads.

By connecting the readout thin-film transistors and photodiodes of the unit pixels arranged in a matrix as described above, it is possible to facilitate readout operation on a line-by-line (row-by-row) basis, thereby enabling acquisition of image data optimized for high-speed image applications.

In this embodiment, two readout thin-film transistors Readout TFT 1, Readout TFT 2 are connected in series to a photodiode. Accordingly, the output current value of the unit pixel according to this embodiment is approximately doubled compared to that of a typical unit pixel using a single readout thin-film transistor. For example, assuming that one readout thin-film transistor outputs a current of 1.0 μA, two readout thin-film transistors connected in series can output a current of about 2.0 μA. Consequently, it is possible to provide an X-ray detection panel with a sensitivity (brightness) approximately doubled compared to typical X-ray detection panels.

Although the unit pixel is shown as including two series-connected readout thin-film transistors Readout TFT 1, Readout TFT 2 in this embodiment, the present invention is not limited thereto and the unit pixel may include three or more series-connected readout thin-film transistors. By increasing the number of readout thin-film transistors connected in series, the output current of the unit pixel can be further increased.

According to this embodiment, the sensitivity of the X-ray detection panel can be enhanced by increasing the output current through series connection of multiple readout thin-film transistors. Unlike typical methods that rely on increase in digital gain of hardware or software-based image processing to improve image brightness, this approach can enhance image brightness without causing adverse effects such as increased image noise, reduced resolution, additional image processing time.

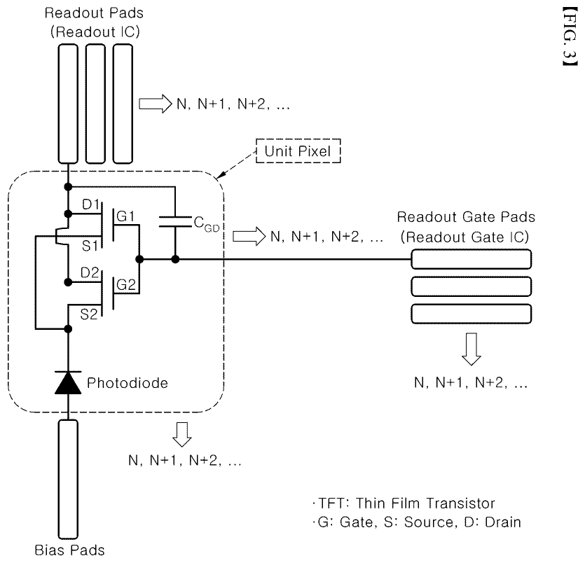

FIG. 3 is a schematic layout diagram of an X-ray detection panel according to another embodiment of the present invention.

Referring to FIG. 3, the X-ray detection panel according to this embodiment is substantially the same as the X-ray detection panel described with reference to FIG. 2 except that the unit pixel further includes a capacitor C_{GD}.

The capacitor C_{GD} may be disposed between a first readout thin-film transistor Readout TFT 1 and a readout gate line. For example, as shown in FIG. 3, the capacitor C_{GD} may be disposed between a drain line of the first readout thin-film transistor Readout TFT 1 and the readout gate line. Since drains D1, D2 are electrically connected to each other and gates G1, G2 are electrically connected to each other, the capacitor C_{GD} is electrically connected to the drain of a second readout thin-film transistor Readout TFT 2 and the readout gate line.

Incorporation of the capacitor CGD into the unit pixel can reduce noise components in a readout output signal. The capacitor may include, for example, at least one of Si, Si—O, Si—N, or Si—O—N, without being limited thereto.

In addition or as an alternative to the capacitor C_{GD}, a dielectric material, for example, at least one of Si—O, Si—N, Si—O—N, or Si—O—N, may be disposed between the drain D1 and the gate G1 and/or between the drain D2 and the gate G2.

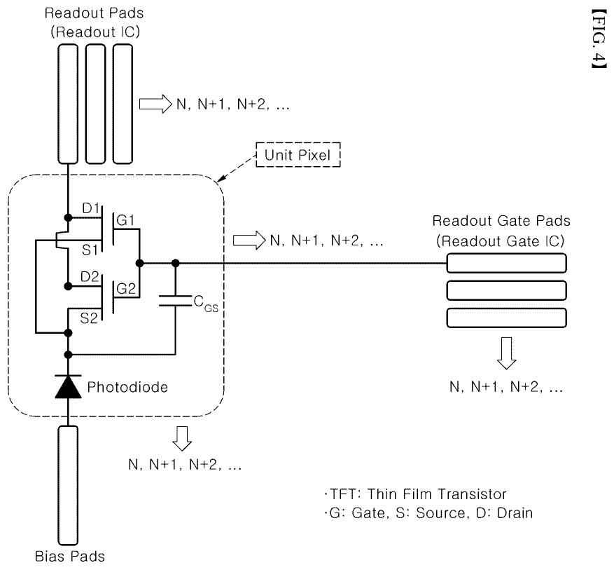

FIG. 4 is a schematic layout diagram of an X-ray detection panel according to a further embodiment of the present invention.

Referring to FIG. 4, the X-ray detection panel according to this embodiment is substantially the same as the X-ray detection panel described with reference to FIG. 2 except that the unit pixel further includes a capacitor C_{GS}.

The capacitor C_{GS} may be disposed between a second readout thin-film transistor Readout TFT 2 and a readout gate line. For example, as shown in FIG. 4, the capacitor C_{GS} may be disposed between a source of the second readout thin-film transistor Readout TFT 2 and the readout gate line. Since sources S1, S2 are electrically connected to each other and gates G1, G2 are electrically connected to each other, the capacitor C_{GS} is also electrically connected to the source of a first readout thin-film transistor Readout TFT 1 and the readout gate line.

Incorporation of the capacitor C_{GS} into the unit pixel can reduce noise components in the gate line. The capacitor may include, for example, at least one of Si, Si—O, Si—N, or Si—O—N, without being limited thereto.

In addition or as an alternative to the capacitor C_{GS}, a dielectric material, for example, at least one of Si—O, Si—N, or Si—O—N, may be disposed between the source S1 and the gate G1 and/or between the source S2 and the gate G2.

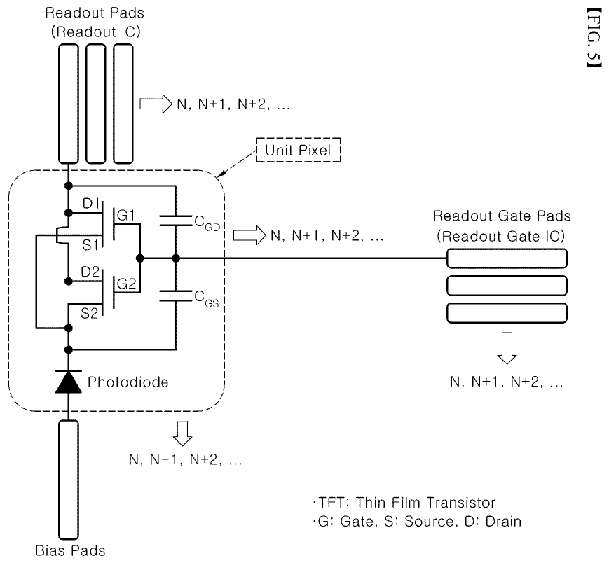

FIG. 5 is a schematic layout diagram of an X-ray detection panel according to yet another embodiment of the present invention.

Referring to FIG. 5, the X-ray detection panel according to this embodiment is substantially the same as the X-ray detection panel described with reference to FIG. 2 except that the unit pixel further includes capacitors C_{GD}, C_{GS}.

Since the capacitors C_{GD}, C_{GS} are identical to the capacitors C_{GD}, C_{GS} described with reference to FIG. 3 and FIG. 4, detailed description thereof will be omitted.

Incorporation of the capacitors CGD, CGS into the unit pixel can reduce noise components in a readout output signal and noise components in the gate line.

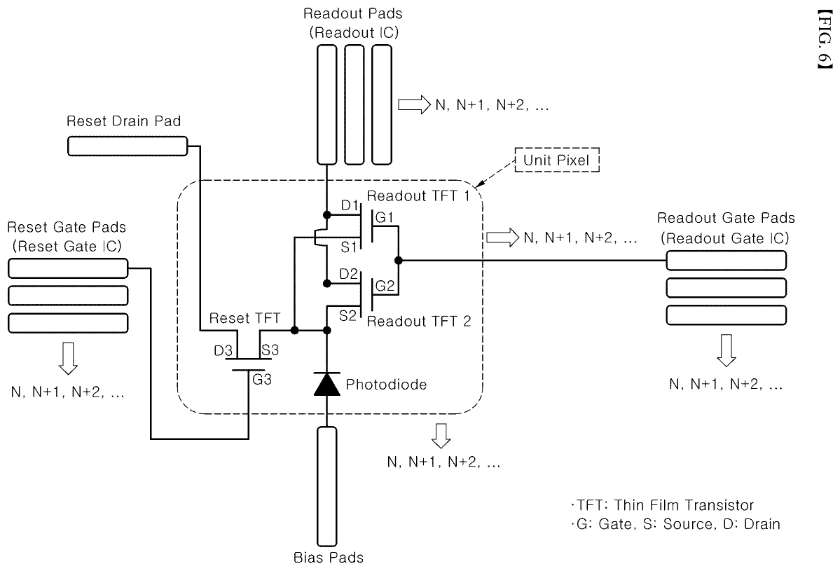

FIG. 6 is a schematic layout diagram of an X-ray detection panel according to yet another embodiment of the present invention.

Referring to FIG. 6, the X-ray detection panel according to this embodiment is substantially the same as the X-ray detection panel described with reference to FIG. 2 except that the unit pixel further includes a reset thin-film transistor Reset TFT. In addition, the X-ray detection panel according to this embodiment further includes reset gate pads and a reset drain pad.

A drain D3 of the reset thin-film transistor Reset TFT is connected to a drain-source voltage terminal Vds through the reset drain pad, and a gate of the reset thin-film transistor Reset TFT is connected to a reset gate IC through the reset gate pad. A source S3 of the reset thin-film transistor Reset TFT may be connected to sources S1, S2 of the first and second readout thin-film transistors Readout TFT 1, Readout TFT 2.

Drains D3 of a plurality of reset thin-film transistors Rest TFTs may be connected in common to a single drain pad. In another embodiment, the X-ray detection panel may be provided therein with a plurality of reset drain pads, wherein each reset drain pad may be connected to a corresponding one of the drains of the plurality of reset thin-film transistors in the detection panel. The plurality of reset drain pads may be arranged vertically and/or horizontally within the detection panel. Incorporation of the plurality of reset drain pads enables reduction in connection length between the unit pixel and the reset drain pad, thereby reducing RC delay.

For unit pixels in the same row, gates of the corresponding reset thin-film transistors Reset TFTs may be connected in common to a single reset gate pad. Conversely, for unit pixels in different rows, gates of the corresponding reset thin-film transistors Reset TFTs may be connected to different reset gate pads. The reset thin-film transistor may be turned on and off by reset gate voltage V_{Reset-Gate} applied to the gate G3.

By turning the reset thin-film transistor Reset TFT on, it is possible to remove parasitic capacitance components accumulated at the photodiode and the first and second readout thin-film transistors Readout TFT 1, Readout TFT 1.

The array of unit pixels (N, N+1, N+2, . . . ) may be reset on a line-by-line basis, that is, on a row-by-row basis. During reset of a line of unit pixels, the reset thin-film transistor Reset TFT is switched to an ON state, whereas the readout thin-film transistors Readout TFT 1, Readout TFT 2 are switched to an OFF state. For instance, the reset thin-film transistor Reset TFT may be switched on as reset gate voltage V_{Reset-Gate} is applied to the gate G3 of the reset thin-film transistor Reset TFT by the reset gate IC, and the readout thin-film transistors Readout TFT 1, Readout TFT 2 are switched off as gate voltage V_{Gate} is applied to the gates G1, G2 of the readout thin-film transistors Readout TFT 1, Readout TFT 2 by the readout gate IC. Additionally, bias voltage V_{Bias} may be applied to the photodiode.

Through this line reset operation, charges remaining in unit pixels connected to the reset gate pad can be removed through the reset thin-film transistor Rest TFT, thereby enabling reset of the corresponding unit pixels. Once reset of one line (row) of unit pixels is completed, reset of the next row of unit pixels may be conducted. In this manner, the array of unit pixels in the X-ray detection panel may be reset on a line-by-line basis.

After reset of the array of unit pixels, a window time may be provided to collect data generated by X-ray irradiation. Herein, the term “window time” refers to an interval in time during which charges generated in the photodiode by X-ray irradiation are accumulated. Duration of the window time may be arbitrarily determined based on the charge saturation time of photodiodes.

During the window time, the reset thin-film transistor Reset TFT and the readout thin-film transistors Readout TFT 1, Readout TFT 2 are switched to the OFF state. Additionally, bias voltage V_{Bias} may be applied to the photodiode.

In response to incident X-rays, the photodiode generates charges through photoelectric conversion. Since the reset thin-film transistor Reset TFT and the readout thin-film transistors Readout TFT 1, Readout TFT 2 are in the OFF state, the charges generated by the photodiode can be accumulated at the photodiode or the sources of the readout thin-film transistors Readout TFT 1, Readout TFT 2.

In a readout step, the reset thin-film transistor Reset TFT remains in the OFF state, and the readout thin-film transistors Readout TFT 1, Readout TFT 2 are switched to the ON state. Additionally, bias voltage V_{Bias} may be applied to the photodiode.

In the readout step, the charges generated by the photodiode move from the sources S1, S2 of the readout thin-film transistors Readout TFT 1, Readout TFT 2 to the drains D1, D2 thereof and then are transferred to the readout IC through the readout pad. The readout IC may generate image data using data on the charges.

The line reset operation, the window time, and the readout step are performed sequentially in this order, thereby processing data of one pixel line. By processing data of each pixel line sequentially, one frame of data for all pixels is acquired. Repetition of this line-by-line data processing process enables acquisition of multiple frames of data and thus implementation of dynamic image.

According to this embodiment, through integration of the reset thin-film transistor Reset TFT into the unit pixel, it is possible to eliminate parasitic capacitance components remaining in the photodiode and the first and second readout thin-film transistors, thereby solving problems such as image lag and ghost images, which are prevalent in typical dynamic X-ray detectors.

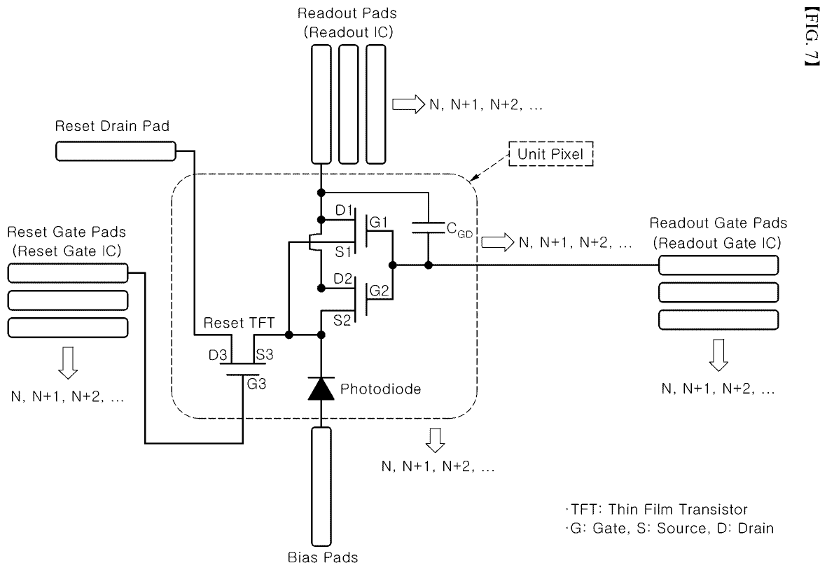

FIG. 7 is a schematic layout diagram of an X-ray detection panel according to yet another embodiment of the present invention.

Referring to FIG. 7, the X-ray detection panel according to this embodiment is substantially the same as the X-ray detection panel described with reference to FIG. 6 except that the unit pixel further includes a capacitor C_{GD}. Since the capacitor C_{GD} is the same as described above with reference to FIG. 3, detailed description thereof will be omitted.

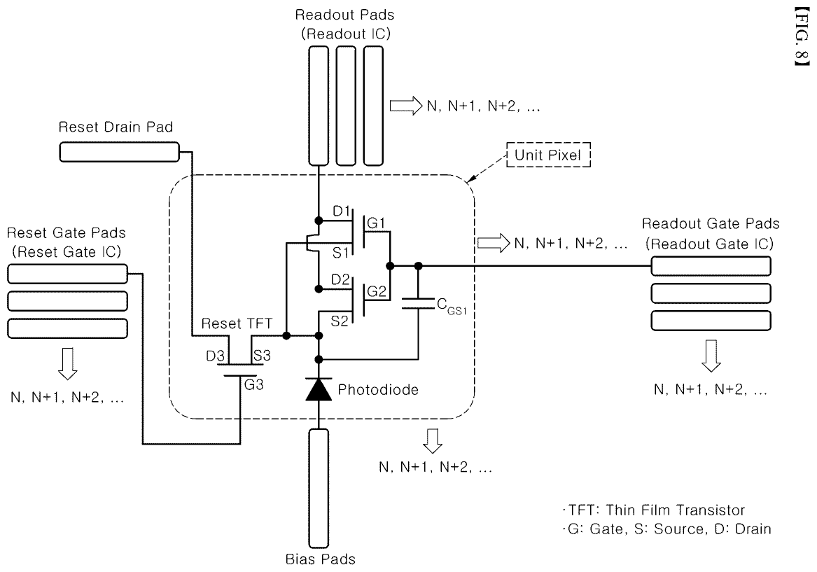

FIG. 8 is a schematic layout diagram of an X-ray detection panel according to yet another embodiment of the present invention.

Referring to FIG. 8, the X-ray detection panel according to this embodiment is substantially the same as the X-ray detection panel described with reference to FIG. 6 except that the unit pixel further includes a capacitor C_{GS1}. Since the capacitor C_{GS1} is identical to the capacitor C_{GS} described with reference to FIG. 4, detailed description thereof will be omitted.

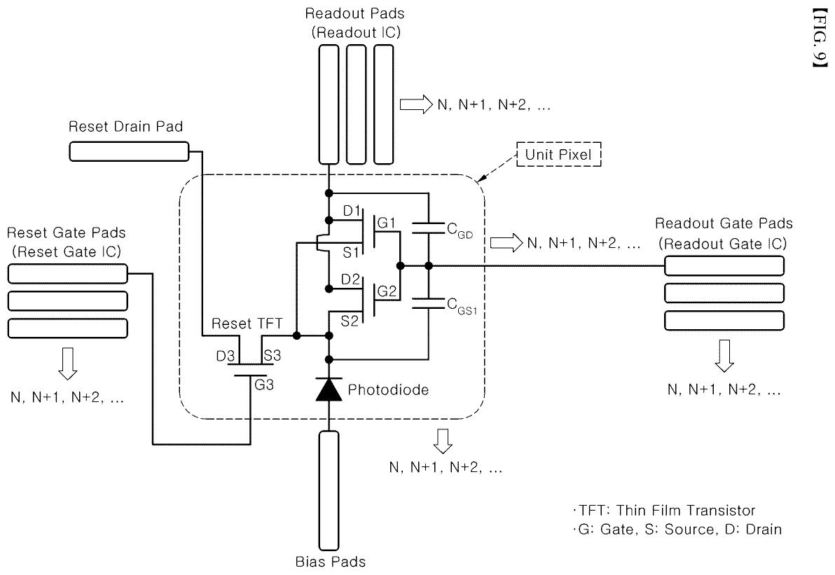

FIG. 9 is a schematic layout diagram of an X-ray detection panel according to yet another embodiment of the present invention.

Referring to FIG. 9, the X-ray detection panel according to this embodiment is substantially the same as the X-ray detection panel described with reference to FIG. 6 except that the unit pixel further includes capacitors C_{GD}, C_{GS1}.

Since the capacitors C_{GD}, C_{GS1} are identical to the capacitors C_{GD}, C_{GS1} described with reference to FIG. 7 and FIG. 8, detailed description thereof will be omitted.

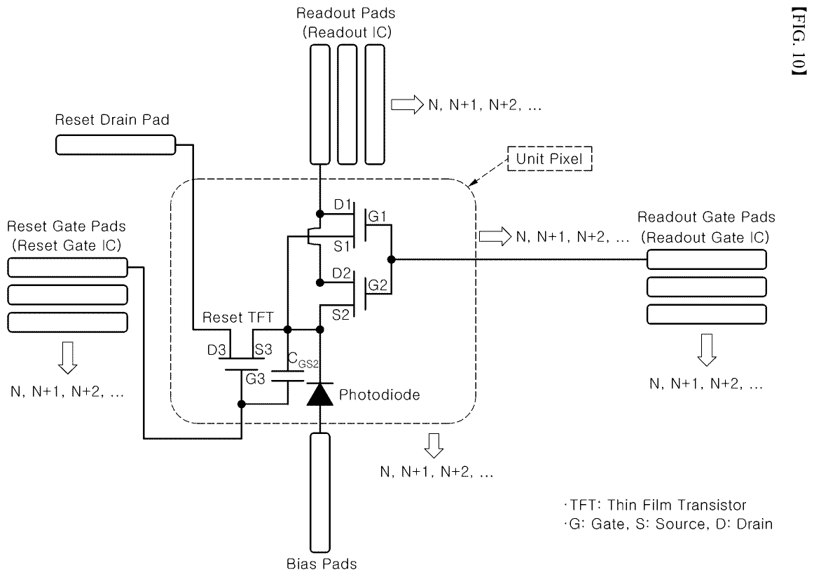

FIG. 10 is a schematic layout diagram of an X-ray detection panel according to yet another embodiment of the present invention.

Referring to FIG. 10, the X-ray detection panel according to this embodiment is substantially the same as the X-ray detection panel described with reference to FIG. 6 except that the unit pixel further includes a capacitor C_{GS2}.

The capacitor C_{GS2} may be disposed between a reset thin-film transistor Reset TFT and a reset gate line. For example, as shown in FIG. 10, the capacitor C_{GS2} may be disposed between a source S3 of the reset thin-film transistor Reset TFT and the reset gate line.

Incorporation of the capacitor C_{GS2} into the unit pixel can reduce noise components in the reset gate line. The capacitor C_{GS2} may include, for example, at least one of Si, Si—O, Si—N, or Si—O—N, without being limited thereto.

In addition or as an alternative to the capacitor C_{GS2}, a dielectric material, for example, at least one of Si—O, Si—N, or Si—O—N, may be disposed between the source S3 and the gate G3.

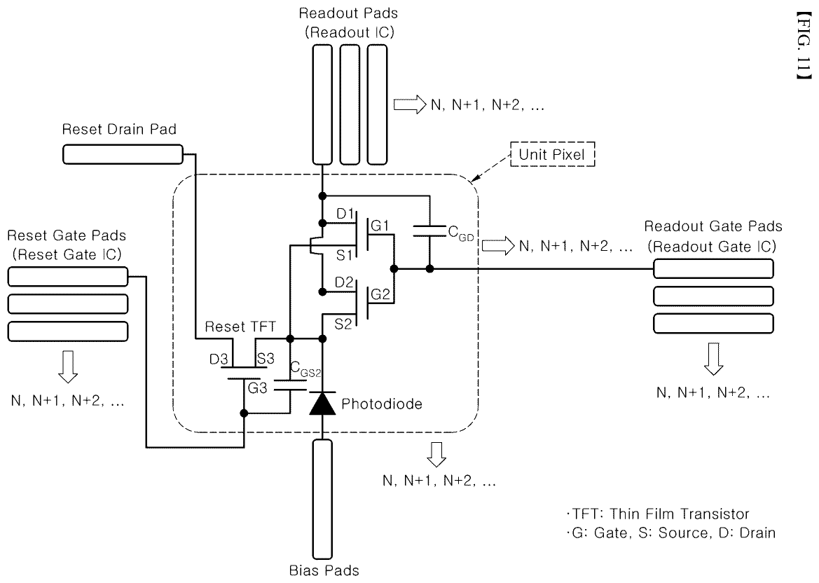

FIG. 11 is a schematic circuit diagram of an X-ray detection panel according to yet another embodiment of the present invention.

Referring to FIG. 11, the X-ray detection panel according to this embodiment is substantially the same as the X-ray detection panel described with reference to FIG. 10 except that the unit pixel further includes a capacitor C_{GD}. Since the capacitor C_{GD} is the same as described above with reference to FIG. 7, detailed description thereof will be omitted.

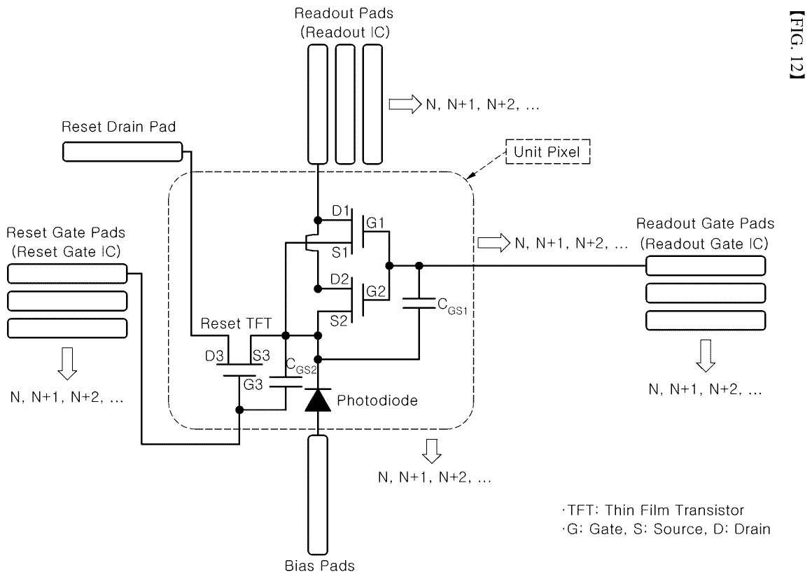

FIG. 12 is a schematic layout diagram of an X-ray detection panel according to one embodiment of the present invention.

Referring to FIG. 12, the X-ray detection panel according to this embodiment is substantially the same as the X-ray detection panel described with reference to FIG. 10 except that the unit pixel further includes a capacitor C_{GS1}. Since the capacitor C_{GS1} is the same as described above with reference to FIG. 8, detailed description thereof will be omitted.

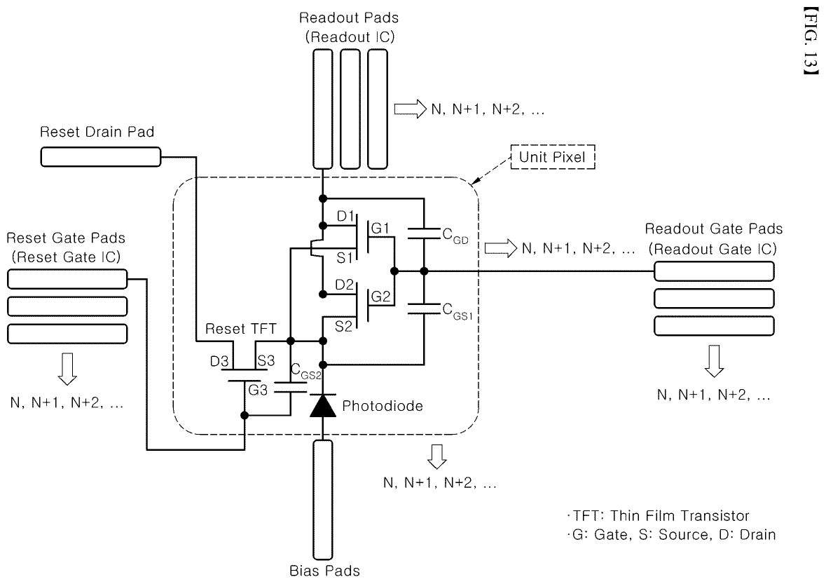

FIG. 13 is a schematic layout diagram of an X-ray detection panel according to yet another embodiment of the present invention.

Referring to FIG. 13, the X-ray detection panel according to this embodiment is substantially the same as the X-ray detection panel described with reference to FIG. 10 except that the unit pixel further includes capacitors C_{GD}, C_{GS1}.

Since the capacitors C_{GD}, C_{GS1} are identical to the capacitors C_{GD}, C_{GS1} described with reference to FIG. 7, FIG. 8, and FIG. 10, detailed description thereof will be omitted.

Although some embodiments have been described, it should be understood that these embodiments are provided for illustration only and are not to be construed in any way as limiting the present invention, and that various modifications, changes, alterations, and equivalent embodiments can be made by those skilled in the art without departing from the spirit and scope of the invention.

1. An X-ray detection panel comprising a plurality of unit pixels,
wherein each unit pixel comprises:
a photodiode;
a first readout thin-film transistor; and
a second readout thin-film transistor,
the first readout thin-film transistor and the second readout thin-film transistor being electrically connected to the photodiode and connected in series to each other.

2. The X-ray detection panel according to claim 1, wherein:
a source of the first readout thin-film transistor and a source of the second readout thin-film transistor are connected in common to the photodiode;
a gate of the first readout thin-film transistor and a gate of the second readout thin-film transistor are connected to each other; and
a drain of the first readout thin-film transistor and a drain of the second readout thin-film transistor are connected to each other.

3. The X-ray detection panel according to claim 2, further comprising:
readout pads;
readout gate pads; and
a bias pad,
wherein the readout pads are connected to the drains of the first and second readout thin-film transistors,
the readout gate pads are connected to the gates of the first and second readout thin-film transistors, and
the bias pad is connected to the photodiode.

4. The X-ray detection panel according to claim 3, wherein:
the gates of the first and second readout thin-film transistors are connected to the readout gate pad through a readout gate line;
the drains of the first and second readout thin-film transistors are connected to the readout pad through a readout drain line;
the photodiode is connected to the sources of the first and second readout thin-film transistors; and
each unit pixel further comprises a capacitor disposed between the first readout thin-film transistor and the readout gate line.

5. The X-ray detection panel according to claim 4, wherein each unit pixel further comprises a capacitor disposed between the second readout thin-film transistor and the readout gate line.

6. The X-ray detection panel according to claim 3, wherein:
the gates of the first and second readout thin-film transistors are connected to the readout gate pad through a readout gate line;
the drains of the first and second readout thin-film transistors are connected to the readout pad through a readout drain line; and
each unit pixel further comprises a capacitor disposed between the second readout thin-film transistor and the readout gate line.

7. The X-ray detection panel according to claim 1, wherein each unit pixel further comprises a reset thin-film transistor, and a source of the reset thin-film transistors is connected to the sources of the first and second readout thin-film transistors.

8. The X-ray detection panel according to claim 7, further comprising:
reset gate pads; and
a reset drain pad,
wherein the reset gate pad is connected to a gate of the reset thin-film transistor, and
the reset drain pad is connected to a drain of the reset thin-film transistor.

9. The X-ray detection panel according to claim 8, wherein:
the sources of the first and second readout thin-film transistors are connected in common to the photodiode;
the gates of the first and second readout thin-film transistors are connected to each other; and
the drains of the first and second readout thin-film transistors are connected to each other.

10. The X-ray detection panel according to claim 9, further comprising:
readout pads;
readout gate pads; and
a bias pad,
wherein the readout pads are connected to the drains of the first and second readout thin-film transistors,
the readout gate pads are connected to the gates of the first and second readout thin-film transistors, and
the bias pad is connected to the photodiode.

11. The X-ray detection panel according to claim 10, wherein:
the gates of the first and second readout thin-film transistors are connected to the readout gate pad through a readout gate line;
the drains of the first and second readout thin-film transistors are connected to the readout pad through a readout drain line;
the photodiode is connected to the sources of the first and second readout thin-film transistors; and
each unit pixel further comprises a capacitor disposed between the first readout thin-film transistor and the readout gate line.

12. The X-ray detection panel according to claim 11, wherein each unit pixel further comprises a capacitor disposed between the second readout thin-film transistor and the readout gate line.

13. The X-ray detection panel according to claim 10, wherein:
the gates of the first and second readout thin-film transistors are connected to the readout gate pad through a readout gate line;
the photodiode is connected to the sources of the first and second readout thin-film transistors; and
each unit pixel further comprises a capacitor disposed between the second readout thin-film transistor and the readout gate line.

14. The X-ray detection panel according to claim 8, wherein:
the gate of the reset thin-film transistor is connected to the reset gate pad through a reset gate line;
the source of the reset thin-film transistor is connected to the sources of the first and second readout thin-film transistors; and
each unit pixel further comprises a capacitor disposed between the reset thin-film transistor and the reset gate line.

15. An X-ray detector comprising an X-ray detection panel, wherein the X-ray detection panel comprises a plurality of unit pixels each comprising: a photodiode; a first readout thin-film transistor; and a second readout thin-film transistor, the first readout thin-film transistor and the second readout thin-film transistor being electrically connected to the photodiode and connected in series to each other.

16. The X-ray detector according to claim 15, wherein each unit pixel further comprises a reset thin-film transistor.

17. A unit pixel for an X-ray detection panel, comprising:
a photodiode;
a first readout thin-film transistor; and
a second readout thin-film transistor,
wherein the first readout thin-film transistor and the second readout thin-film transistor are electrically connected to the photodiode and are connected in series to each other.

18. The unit pixel according to claim 17, further comprising:
at least one capacitor connected to the first readout thin-film transistor or the second readout thin-film transistor.

19. The unit pixel according to claim 17, further comprising:
a reset thin-film transistor.

20. The unit pixel according to claim 19, further comprising:
at least one capacitor connected to one of the first readout thin-film transistor, the second readout thin-film transistor, and the reset thin-film transistor.
